(19) United States
(12) Patent Application Publication
(10) Pub. No.: US 2015/0147873 A1
(43) Pub. Date: May 28, 2015

(54) METHOD OF MANUFACTURING SEMICONDUCTOR DEVICE, SUBSTRATE PROCESSING APPARATUS, AND NON-TRANSITORY COMPUTER-READABLE STORAGE MEDIUM

(71) Applicant: HITACHI KOKUSAI ELECTRIC INC, Tokyo (JP)

(72) Inventors: Atsushi MORIYA, Toyama-shi (JP); Kensuke HAGA, Toyama-shi (JP); Kazuhiro YUASA, Toyama-shi (JP); Kaichiro MINAMI, Toyama-shi (JP)

(73) Assignee: HITACHI KOKUSAI ELECTRIC INC, Tokyo (JP)

(21) Appl. No.: 14/549,805

(22) Filed: Nov. 21, 2014

(30) Foreign Application Priority Data
Nov. 22, 2013 (JP) 2013-242129
Oct. 23, 2014 (JP) 2014-216582

(51) Int. Cl. H01L 21/02; H01L 21/67

(52) U.S. Cl. CPC H01L 21/02658; H01L 21/02381; H01L 21/02532; H01L 21/0262; H01L 21/67017; H01L 21/67098
USPC 438/492; 118/702; 118/697

(57) ABSTRACT

Provided is a method of manufacturing a semiconductor device. The method includes: carrying a substrate, which has a Ge-containing film on at least a portion of a surface thereof, into a process chamber; heating an inside of the process chamber, into which the substrate is carried, to a first process temperature; and terminating a surface of the Ge-containing film, which is exposed at a portion of the surface of the substrate, by Si by supplying at least a Si-containing gas to the inside of the process chamber heated to the first process temperature.

### BACKGROUND OF THE INVENTION

1. Field of the Invention

The present invention relates to a method of manufacturing a semiconductor device, a substrate processing apparatus, and anon-transitory computer-readable storage medium, which are used in a semiconductor device manufacturing process.

2. Description of the Related Art

Recently, miniaturization of semiconductor devices, a high driving speed, and reduction of power consumption are required.

However, due to the miniaturization of a semiconductor device, the length of a gate of a transistor device decreases, and thus a leakage current increases and reduction of power consumption is obstructed. On the contrary, when a leakage current is to be suppressed, a different problem such that a current driving speed is reduced occurs.

As an approach to solve this problem, a strained silicon (Si) technology is expected. This technology improves the mobility of holes and electrons by reduction of an effective mass and reduction of carrier diffusion by lattice vibration by changing an energy band structure by distorting a crystal lattice of Si by applying a compressive stress or a tensile stress to a channel region of a metal oxide semiconductor field effect transistor (MOSFET).

In order to apply a compressive stress or a tensile stress to a channel region of a MOSFET, a so-called embedded transistor, in which Si is epitaxially grown in a source/drain region, is proposed.

### SUMMARY OF THE INVENTION

On the other hand, in addition to miniaturization, as a means for improving the performance of a semiconductor device, conversion from a planer-type two-dimensional structure to a fin-type three-dimensional structure and use of a material such as silicon germanium (SiGe) and germanium (Ge) having higher electron/hole mobility than Si in a channel portion are considered.

An object of the present invention is to provide a semiconductor device manufacturing method, a substrate processing apparatus, and non-transitory computer-readable storage medium, in which a SiGe film or a Ge film containing a high concentration of Ge atoms is used in a channel portion.

There is provided a method of manufacturing a semiconductor device, including:

carrying a substrate, which has a Ge-containing film on at least a portion of a surface thereof, into a process chamber;

heating an inside of the process chamber, into which the substrate is carried, to a first process temperature; and

terminating a surface of the Ge-containing film, which is exposed at a portion of the surface of the substrate, by Si by supplying at least a Si-containing gas to the inside of the process chamber heated to the first process temperature.

According to the present invention, it is possible to provide a semiconductor device manufacturing technology that makes it possible to increase a driving speed and reduce power consumption.

### BRIEF DESCRIPTION OF THE DRAWINGS

FIG. 1 is a schematic diagram illustrating a configuration of a substrate processing apparatus according to an embodiment of the present invention;

FIG. 2 is a cross-sectional view illustrating a configuration of a process furnace of a substrate processing apparatus according to an embodiment of the present invention;

FIG. 3 is a diagram illustrating a configuration of a gas supply system of a substrate processing apparatus according to an embodiment of the present invention;

FIG. 4A is a diagram illustrating forming an STI portion and a channel portion in a fin-type structure on a Si substrate;

FIG. 4B is a diagram illustrating exposing a portion of a channel portion by etching an STI portion;

FIG. 4C is a diagram illustrating forming a cap layer on an exposed channel portion;

FIG. 4D is a diagram illustrating forming a gate insulating film and a gate film on a cap layer;

FIG. 5A is a diagram illustrating forming an STI portion and a channel portion on a Si substrate;

FIG. 5B is a diagram illustrating forming a cap layer on a channel portion;

FIG. 5C is a schematic diagram of a semiconductor device in which a source/drain portion and a gate portion are formed;

FIG. 6A is a diagram illustrating a substrate processing flow of a substrate processing apparatus according to an embodiment of the present invention;

FIG. 6B is a diagram illustrating a film deposition process of a substrate processing flow of a substrate processing apparatus according to an embodiment of the present invention;

FIG. 7 is a diagram illustrating an analysis of an interface of a substrate processed by a film deposition flow of a substrate processing apparatus according to an embodiment of the present invention;

FIG. 8A is a diagram illustrating a substrate processing flow of a substrate processing apparatus according to a second embodiment of the present invention;

FIG. 8B is a diagram illustrating a film deposition process of a substrate processing flow of a substrate processing apparatus according to a second embodiment of the present invention;

FIG. 9 is a diagram illustrating an analysis of an interface of a substrate processed by a film deposition flow of a substrate processing apparatus according to a second embodiment of the present invention;

FIG. 10A is a diagram illustrating a substrate processing flow of a substrate processing apparatus according to a third embodiment of the present invention;

FIG. 10B is a diagram illustrating a film deposition process of a substrate processing flow of a substrate processing apparatus according to a third embodiment of the present invention; and

FIG. 11 is a diagram illustrating an analysis of an interface of a substrate processed by a film deposition flow of a substrate processing apparatus according to a third embodiment of the present invention.

### DETAILED DESCRIPTION OF THE PREFERRED EMBODIMENTS

### Embodiment of Present Invention

Hereinafter, embodiments of the present invention will be described with reference to the drawings.

(1) Configuration of Substrate Processing Apparatus

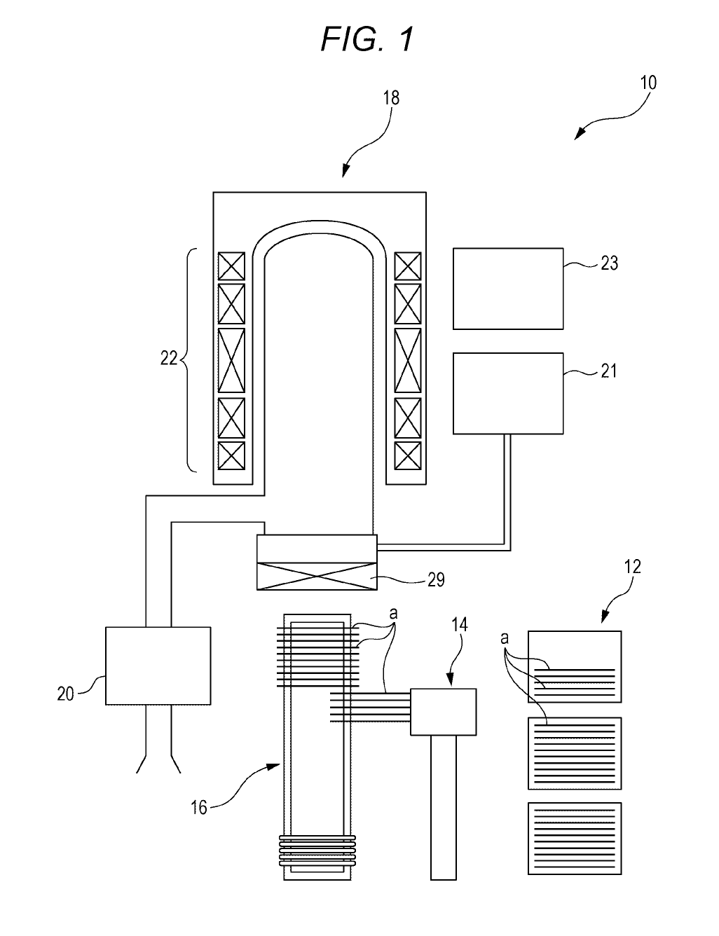

FIG. 1 is a schematic diagram illustrating a configuration of a substrate processing apparatus 10 according to the present embodiment.

The substrate processing apparatus 10 is a so-called hot wall type vertical decompression apparatus. As illustrated in FIG. 1, a wafer (substrate) a carried by a wafer cassette 12 is transferred from the wafer cassette 12 to a boat 16 by a transfer mechanism 14. The transfer of the wafer a to the boat 16 is performed in a standby chamber, and when the boat 16 exists in the standby chamber, a process chamber is hermetically held by a furnace port gate valve 29. When the transfer of the wafer a (as a processing target) to the boat 16 is completed, the furnace port gate valve 29 is moved, a furnace port portion is opened, the boat 16 is inserted into a process furnace 18, and the process furnace 18 is decompressed by a vacuum exhaust system 20. Then, the inside of the process furnace 18 is heated to a desired temperature by a heater 22 that is a heating device, a raw material gas and an etching gas are alternately supplied from a gas supply unit 21 to a timing in which a temperature is stabilized, and Si or SiGe is selectively epitaxially grown on the wafer a. A control system (control device) 23 controls rotation and insertion of the boat 16 into the process furnace 18 according to the driving of the furnace port gate valve 29, exhaustion by the vacuum exhaust system 20, supply of a gas from the gas supply unit 21, and heating by the heater 22.

A Si-containing gas such as SiH₄, Si₂H₆, or SiH₂Cl₂ is used as a raw material gas for selective epitaxial growth of Si or SiGe, and in the case of SiGe, a Ge-containing gas such as GeH₄ and GeCl₄ is further added. Growth is immediately started on Si, SiGe, or Ge into which the raw material gas is introduced, while a growth delay referred to as a latent period is generated on an insulating film such as SiO₂ or SiN. Growth of Si or SiGe only on Si, SiGe, or Ge in this latent period is selective growth. Si core formation (discontinuous Si film formation) is generated on a SiO₂ or SiN insulating film in the selective growth, and selectivity is diminished. Thus, after supply of the raw material gas, an etching gas is supplied to remove a Si core (Si film) formed on an insulating film such as SiO₂ or SiN. This is repeated to perform the selective epitaxial growth.

Next, a detailed configuration of the process furnace 18 of the substrate processing apparatus 10 after insertion of the boat 16 according to an embodiment of the present invention will be described with reference to the drawings.

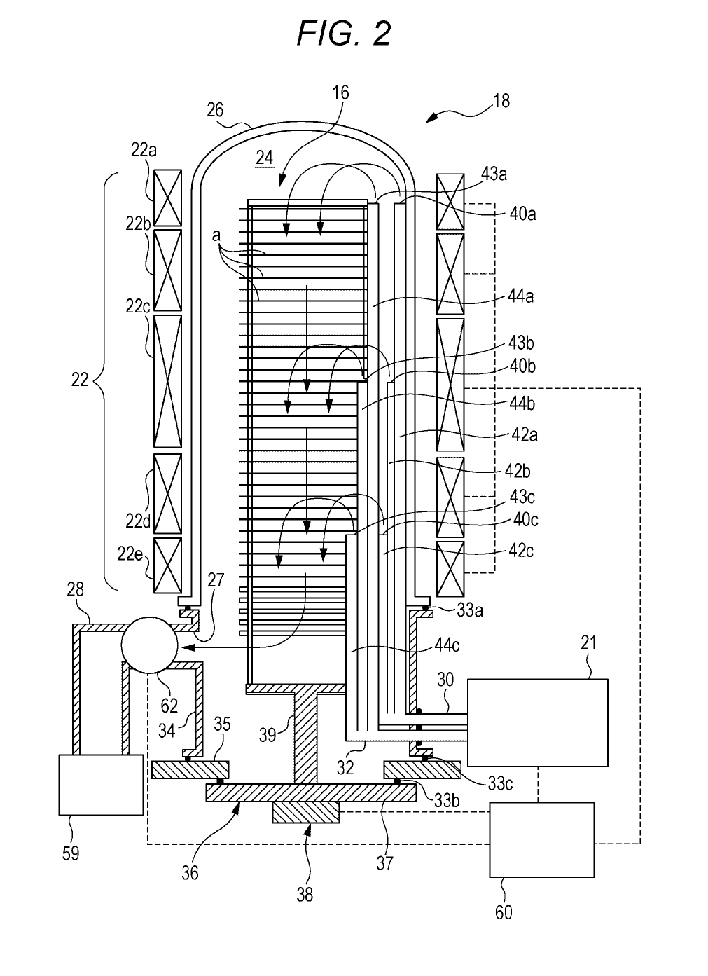

FIG. 2 is a cross-sectional view illustrating a schematic configuration of the process furnace 18 after insertion of the boat 16 according to an embodiment of the present invention. As illustrated in FIG. 2, the process furnace 18 includes a reaction tube 26 constituted by, for example, an outer tube forming a process chamber 24, a gas exhaust pipe 28 disposed under the reaction tube 26 to exhaust a gas from an exhaust port 27, a first gas supply pipe 30 supplying a raw material gas and others to an inside of the process chamber 24, and a second gas supply pipe 32 supplying an etching gas and others, are provided, and a manifold 34 connected to the reaction tube 26 through an O-ring 33a, a seal cap 36 closing a lower end portion of the manifold 34 to seal the process chamber 24 through O-rings 33b and 33c, a boat 16 functioning as a substrate holding unit (substrate supporting unit) holding (supporting) a wafer a in multistage, a rotation mechanism 38 rotating the boat 16 at a predetermined rotation speed, a heater (heating device) 22 disposed outside the reaction tube 26 and constituted by a heat insulation member and a heater line (not illustrated) to heat the wafer a.

The reaction tube 26 is made of, for example, a heat resistance material such as quartz (SiO₂) or silicon carbide (SiC), and is formed to have a cylindrical shape with a closed upper end and an opened lower end. The manifold 34 is made of, for example, stainless or the like and is formed to have a cylindrical shape with an opened upper end and an opened lower end, and the opened upper end supports the reaction tube 26 through the O-ring 33a. The seal cap 36 is made of, for example, stainless or the like and is formed by a ring shape portion 35 and a disk shape portion 37 to close a lower end portion of the manifold 34 through the O-rings 33b and 33c. Also, the boat 16 is made of, for example, a heat resistance material such as quartz or silicon carbide and is configured to hold a plurality of wafers a in multistage with their centers aligned with each other in a horizontal posture. The rotation mechanism 38 of the boat 16 is configured to rotate the wafer a by rotating the boat 16 by being connected to the boat 16 with a rotation axis 39 passing through the seal cap 36.

Also, the heater 22 is divided into five regions of an upper heater 22a, a center upper heater 22b, a center heater 22c, a center lower heater 22d, and a lower heater 22e, and each of them has a cylindrical shape.

In the process furnace 18, three first gas supply nozzles 42a, 42b, and 42c having first gas supply ports 40a, 40b, and 40c of different heights are disposed to constitute a first gas supply system 30. Also, in separation from the first gas supply nozzles 42a, 42b, and 42c, three second gas supply nozzles 44a, 44b, and 44c having second gas supply ports 43a, 43b, and 43c of different heights are disposed to constitute a second gas supply system 32. The first gas supply system 30 and the second gas supply system 32 are connected to the gas supply unit 21.

In the configuration of the process furnace 18, a raw material gas (for example, SiH₄ gas) is supplied to three places of the upper portion, the center portion, and the lower portion of the boat 16 by the first gas supply nozzles 42a, 42b, and 42c of the first gas supply system 30, and an etching gas (for example, Cl₂ gas) is supplied to three places of the upper portion, the center portion, and the lower portion of the boat 16 by the second gas supply nozzles 44a, 44b, and 44c of the second gas supply system 32. Also, while the raw material gas is supplied from the first gas supply system 30, a purge gas (for example, H₂ gas) is supplied to the second gas supply system 32, and while the etching gas is supplied from the second gas supply system 32, the purge gas is supplied from the first gas supply system 30, so that a backflow of an another gas inside the nozzle is suppressed. Also, an atmosphere in the process chamber 24 is exhausted from the gas exhaust pipe 28 functioning as a gas exhaust system. The gas exhaust pipe 28 is connected to a gas exhaust unit (for example, a vacuum pump 59). The gas exhaust pipe 28 is disposed under the process chamber 24, and a gas ejected from the gas supply nozzles 42 and 44 flows from the upper portion toward the lower portion as illustrated in FIG. 2. In this manner, since the gas flows from the upper portion toward the lower portion, the gas passing through the lower portion of the process chamber 24 in which lower-temperature by-products are easily generated may not contact the wafer a, and the improvement of a film quality may be expected.

Also, the substrate processing apparatus 10 includes a control system (control device) 60 and are electrically connected to the gas supply unit 21, the heater 22, the rotation mechanism 38 of the boat 16, and the vacuum pump 59 to control their respective operations.

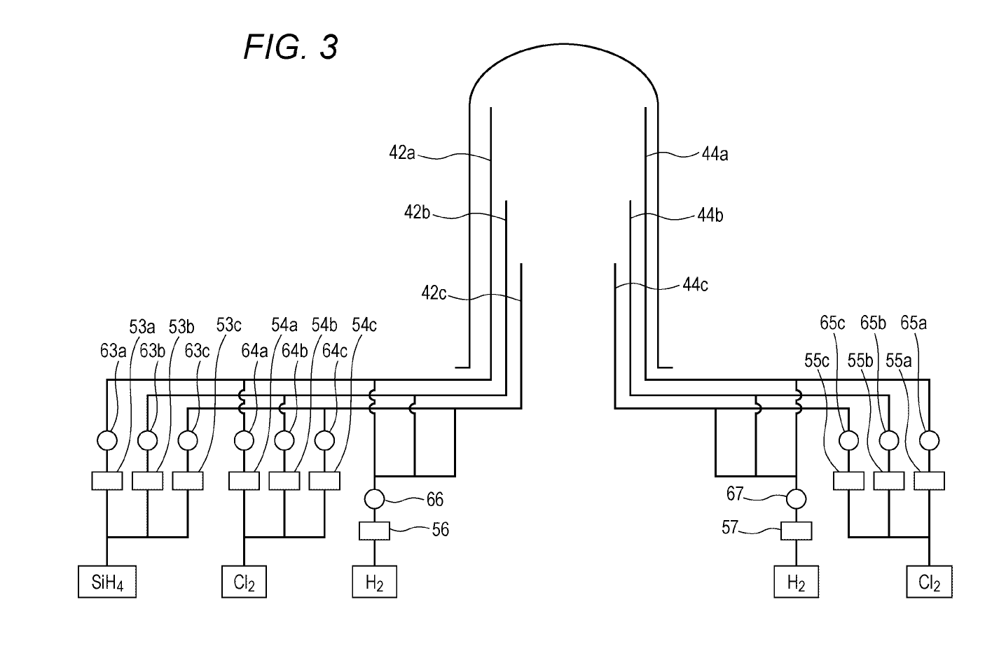

Next, the first gas supply system 30, the second gas supply system 32, and a gas supply unit 45 will be described with reference to FIG. 3. For simplicity of description, FIG. 3 illustrates only a gas supply part of the substrate processing apparatus according to the present embodiment.

The first gas supply nozzles 42a, 42b, and 42c constituting the first gas supply system 30 are respectively connected to a SiH₄ supply source functioning as a raw material gas supply source through first valves 63a, 63b, and 63c and first mass flow rate controllers (hereinafter referred to as “MFCs”) 53a, 53b, and 53c functioning as a gas flow rate control unit. Also, the first gas supply nozzles 42a, 42b, and 42c are respectively connected to a Cl₂ supply source functioning as an etching gas supply source through second valves 64a, 64b, and 64c and second MFCs 54a, 54b, and 54c functioning as a gas flow rate control unit. Also, the first gas supply nozzles 42a, 42b, and 42c are respectively connected to an H₂ supply source functioning as a purge gas supply source through a fourth valve 66 and a fourth MFC 56.

The second gas supply nozzles 44a, 44b, and 44c constituting the second gas supply system 32 are respectively connected to a Cl₂ supply source functioning as an etching gas supply source through third valves 65a, 65b, and 65c and third MFCs 55a, 55b, and 55c functioning as a gas flow rate control unit. Also, the second gas supply nozzles 44a, 44b, and 44c are respectively connected to an H₂ supply source functioning as a purge gas supply source through a fifth valve 67 and a fifth MFC 57.

In the present embodiment, the first gas supply pipe 30 and the first gas supply nozzles 42a, 42b, and 42c supplying the raw material gas into the process chamber 24 are separated from the second gas supply pipe 32 and the second gas supply nozzles 44a, 44b, and 44c supplying the etching gas into the process chamber 24. Thus, since the raw material gas and the etching gas are supplied from different nozzles, the amount of the raw material gas and the amount of the etching gas may be independently adjusted.

Also, when the raw material gas and the etching gas are supplied from the same nozzle, a film adheres to the inside of the nozzle due to autolysis of the raw material gas. Thus, when the etching gas flows therethrough, particles or etching gas consumption is generated. On the other hand, in the present embodiment, since the raw material gas and the etching gas are supplied from different nozzles, generation of particles in the nozzle may be prevented. Also, since a film does not adhere to the inner walls of the second gas supply nozzles 44a, 44b, and 44c supplying the etching gas, the etching gas is not consumed in the second gas supply nozzles 44a, 44b, and 44c. Thus, better etching characteristics may be obtained, and a stable etching rate may be ensured with respect to the wafer a regardless of the states of the inner walls of the first gas supply nozzles 42a, 42b, and 42c and the second gas supply nozzles 44a, 44b, and 44c.

Also, the etching gas may be supplied from the first gas supply nozzles 42a, 42b, and 42c. As described above, it may be preferable to independently supply the raw material gas and the etching gas in a selective growth process, and in this regard, the etching gas may not need to be supplied to the first gas supply nozzles 42a, 42b, and 42c supplying the raw material gas. However, since the first gas supply nozzles 42a, 42b, and 42c supply the raw material gas and do not supply the etching gas in the selective growth process, a Si film may be deposited to generate a nozzle blockage. Thus, as in the present embodiment, when the etching gas may also be supplied from the first gas supply nozzle supplying the raw material gas, a Si film deposited on the inner wall of the first gas supply nozzle may be removed.

Also, since a plurality of nozzles of different heights are provided for each of the raw material gas and the etching gas, it may be adjusted by intermediate supply of the gas between the upper portion and the lower portion of the process furnace 18, and the reduction of a growth rate to that of a gas exhaust side (a lower portion in the process furnace 18) by reaction gas consumption may be suppressed. Particularly, in the present embodiment, the first MFCs 53a, 53b, and 53c and the first valves 63a, 63b, and 63c are disposed respectively for the first gas supply nozzles 42a, 42b, and 42c. Also, the third MFCs 55a, 55b, and 55c and the third valves 65a, 65b, and 65c are disposed respectively for the second gas supply nozzles 44a, 44b, and 44c. In this manner, since a valve or a MFC is disposed for each gas supply nozzle, a flow rate of the gas supplied from each gas supply port may be adjusted and a variation in the film thickness due to a difference in the height of the wafer a may be further reduced.

Also, in the present embodiment, the fourth MFC 56 and the fourth valve 66 disposed corresponding to a purge gas supply source are common to three first gas supply nozzles 42a, 42b, and 42c of different heights. Likewise, the fifth MFC 57 and the fifth valve 67 disposed corresponding to a purge gas supply source are common to three second gas supply nozzles 44a, 44b, and 44c of different heights. Since the purge gas does not directly contribute to film deposition, a flow rate may not need to be changed at the height position and a component count increase may be suppressed by commonalization. Also, for the purge gas, a component count may increase, and an MFC and a valve may be independently disposed for each of the nozzles of different heights.

(2) Substrate Processing Process

Next, an example of substrate processing according to the present embodiment will be described with reference to the drawings.

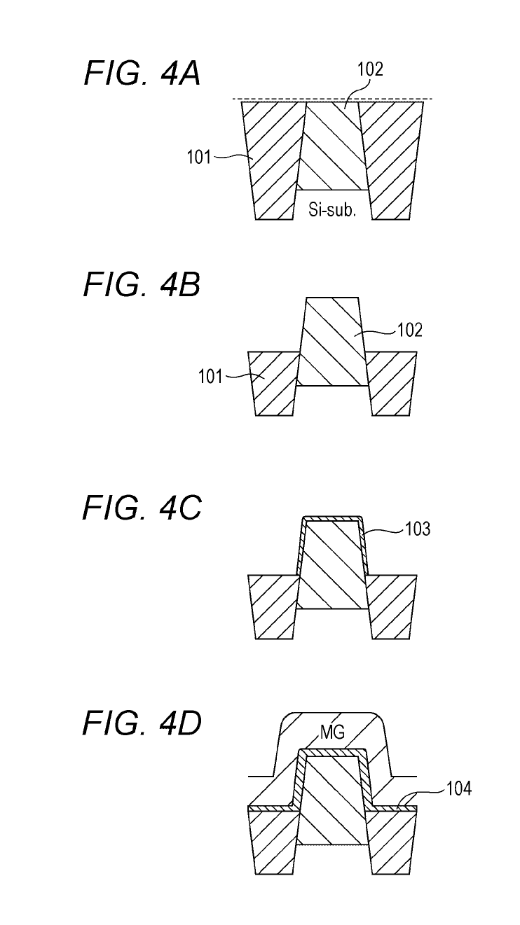

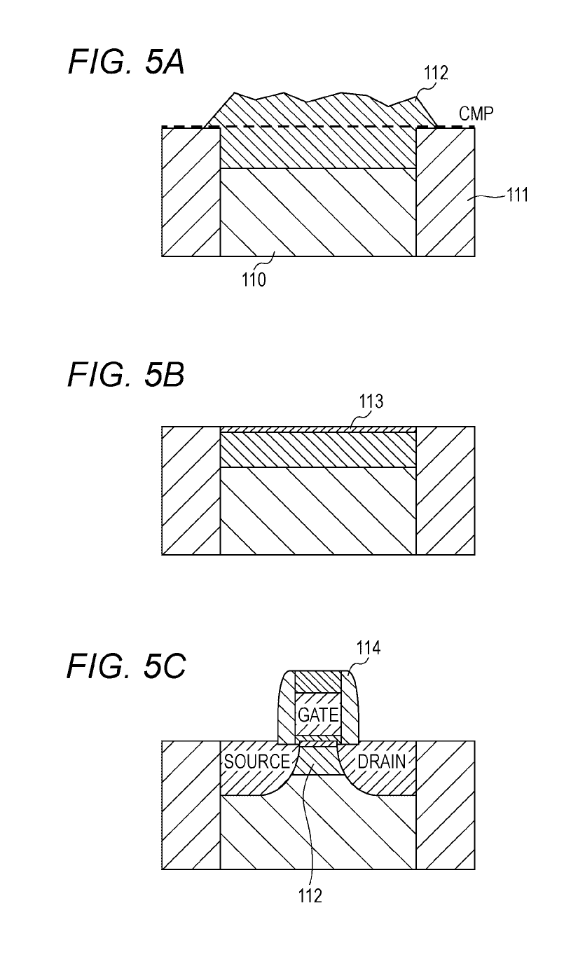

FIGS. 4A to 4D briefly illustrate a device structure and a fabrication method in the case where silicon germanium (SiGe) or germanium (Ge) is used in a channel portion of a fin-FET. Also, FIGS. 5A to 5C briefly illustrate a device structure and a fabrication method in the case where silicon germanium (SiGe) or germanium (Ge) is used in a channel portion of a planer-type MIS-FET.

When SiGe or Ge is used in the channel portion, a silicon (Si) thin film needs to be deposited as a cap layer on the surface of a SiGe or Ge channel portion. The cap layer is to prevent an interface state (defect) from occurring between high-k films stacked on a SiGe or Ge film as a gate insulating film, due to an Ge oxide film formed on a SiGe or Ge surface.

For example, in the case where a Si substrate is used as a material for a wafer, since the surface roughness of a SiGe or Ge film formed on a wafer having a great lattice constant is increased, Si, SiGe, or Ge may not need to be planarized by CMP. Also, in the case of a three-dimensional semiconductor device such as fin-FET, a channel portion needs to be processed in a fin shape. Since the planarization and shaping process is performed by an apparatus different from a film deposition apparatus, the wafer on which a SiGe or Ge film is deposited is exposed to the atmosphere, and in this case, a natural oxide film is formed on the surface of the SiGe or Ge film. Also, in the case where a seal-type substrate storage container such as a FOUP or a Pod is used in order to prevent a wafer from being exposed to the atmosphere when the wafer is carried between devices, when only a few oxygen atoms (O atoms) exist in a process chamber of a film deposition apparatus, a natural oxide film is formed on the surface of the SiGe film or the Ge film during a processing procedure (process) such as temperature raise in a film deposition process.

When a natural oxide film is formed on the surface of the SiGe or Ge film, the mobility of electrons or holes is reduced in the interface of a Si thin film functioning as a cap layer and thus desired characteristics of the film may not be obtained. Therefore, the interface between the channel portion and the cap layer needs to be a clean interface from which impurities such as oxygen are removed.

(Formation of Channel Portion)

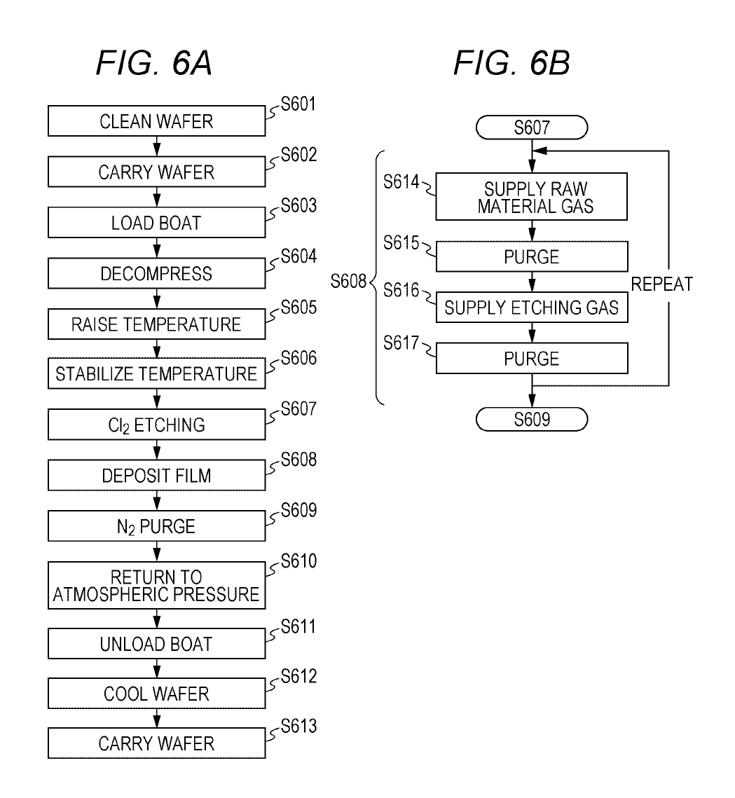

Next, a process of forming a SiGe film or a Ge film in a channel portion will be described with reference to FIGS. 6A and 6B.

First, a wafer is cleaned by a cleaning device (S601), and the wafer after removal of a natural oxide film is carried to a substrate processing apparatus by an in-plant carrying apparatus. The wafer carried to the substrate processing apparatus is carried to a boat 16 functioning as a substrate holder (S602), and the boat 16 is loaded (S603).

Thereafter, an inside of a furnace is decompressed by controlling the vacuum pump 59 (S604), and the temperature of the inside of the process chamber 24 is raised to a process temperature (for example, 500° C.) at the timing when the pressure of the inside of the process chamber 24 is adjusted to a predetermined pressure (S605). At the timing when the temperature is stabilized at the process temperature (S606), an etching gas is supplied by the second gas supply system 32, and wafer etching as preprocessing is performed to remove impurities of the surface of the wafer (S607). The impurities of the surface of the wafer are removed, a raw material gas is supplied, and film deposition processing is performed (S608).

As illustrated in FIG. 6B, the film deposition processing is performed in the sequence of a process of supplying a raw material gas such as a Si-containing gas or a Ge-containing gas (S614), a purge process of purging the raw material gas inside the process chamber 24 (S615), a process of supplying an etching gas such as a Cl-containing gas (S616), and a purge process of supplying an H₂ gas and purge the etching gas inside the process chamber 24 (S617), and a cycle of raw material gas supply, raw material gas purge, etching gas supply, and etching gas purge is repeated until a predetermined thickness is obtained or a predetermined cycle count is reached.

By the above the film deposition processing, a SiGe film or a Ge film is formed in the channel portion.

After the predetermined thickness is obtained, a process of supplying an inert gas from an inert gas supply source (for example, N₂) (not illustrated) and exhausting an H₂ gas from the inside of the process chamber 24 is performed (S609). After purging by the inert gas, the pressure inside the process chamber 24 is returned to the atmospheric pressure (S610), the boat 16 is carried out from the process chamber 24 (S611), and the wafer is cooled (S612). When the wafer is cooled, the wafer is carried to a predetermined apparatus for planarization of the deposited SiGe or Ge film or the fin-type shaping process (S613).

The above channel portion forming process will now be described in detail. The wafer is carried to the cleaning apparatus, and the wafer is cleaned by the cleaning apparatus, for example, at 1% DHF for 60 seconds to remove impurities or a natural oxide film formed on the surface of the wafer.

The wafer from which the impurities or the natural oxide film is removed is loaded into the process chamber 24 that is mounted on the boat 16 by an in-plant carrying apparatus (not illustrated). Thereafter, the inside of the process chamber 24 is decompressed by the vacuum pump 59, and then the temperature of the atmosphere inside the process chamber 24 is raised to about 500° C. by the heater 22. When the temperature of the inside of the process chamber 24 is raised to about 500° C., a Cl₂ gas is supplied as preprocessing, that is, pre-cleaning and the surface of the wafer is etched, for example, by about 50 Å.

After the impurities of the surface of the wafer are removed by the pre-cleaning, a process of maintaining the temperature of the inside of the process chamber 24 at about 500° C. as film deposition processing and sequentially supplying a SiH₄ gas and a GeH₄ gas as a raw material gas, a Cl₂ gas as an etching gas, and an H₂ gas as a purge gas is repeated in turn, so that a SiGe film having a Ge concentration of, for example, 32% is epitaxially grown to a thickness of about 350 nm to be formed as the channel portion.

When the desired film is formed in the channel portion, the inside of the process chamber 24 is purged by an N₂ gas and then the boat 16 is unloaded.

Here, as for the type of the gas used as the raw material gas for SiGe film deposition, the Si-containing gas may be generally a Si atom-containing gas such as SiH₄, SiH₂Cl₂, SiHCl₃, or SiCl₄, and the Ge-containing gas may be GeH₄ or GeCl₄. Also, the etching gas is not limited to the Cl-containing gas such as a hydrogen chloride (HCl) gas or a chlorine (Cl₂) gas, but may be a halogen-containing gas such as a fluorine (F₂) gas, a hydrogen fluoride (HF) gas, or a chlorine trifluoride (ClF₃) gas.

(Planarization/Shaping Process)

The wafer on which the SiGe film or the Ge film is formed by the channel portion forming process is carried to a predetermined apparatus such as a CMP apparatus, and the planarization or shaping of the surface of the SiGe film or the Ge film is performed.

After the planarization or shaping of the SiGe film or the Ge film on the surface of the wafer is performed, the wafer is carried to a cleaning apparatus by an in-plant carrying apparatus (not illustrated), impurities or a natural oxide film on the surface of the wafer is removed, and the surface of the wafer is terminated by hydrogen atoms (H atoms). Thereafter, for formation of a cap layer, the wafer is carried to the substrate processing apparatus by an in-plant carrying apparatus (not illustrated).

(Formation of Cap Layer)

A cap layer is formed on the planarized or shaped wafer.

A wafer processing sequence in the cap layer formation is substantially identical to the processing sequence illustrated in FIG. 6 described in the channel portion forming process, and is different from the channel portion forming process in terms of the type of a raw material gas supplied into the process chamber 24 in a film deposition process, the type of an etching gas, and processing parameters such as the temperature of the inside of the process chamber and the pressure of the inside of the process chamber.

A wafer processing process for formation of the cap layer will be described below.

The wafer a received in the wafer cassette 12 is transferred to the boat 16 as a substrate holding unit by using the transfer mechanism 14 (wafer carrying process). Also, the wafer a has a surface at which a SiGe film or a Ge film is exposed and a surface that is covered with an insulating film (SiN or SiO₂). Next, the boat 16 holding the unprocessed wafer a is inserted into the process chamber 24 by moving the furnace port gate valve 29, opening a furnace port portion, and driving an elevating motor (not illustrated) (boat loading process). Next, in response to a command from the control device 60, an exhaust valve 62 is opened to exhaust the atmosphere of the inside of the process chamber 24 and decompress the inside of the process chamber 24 (decompression process). Then, by controlling the heater 22 by the control device 60, the temperature of the process chamber 24 is raised (temperature raising process) such that the temperature of the inside of the process chamber 24 and the temperature of the wafer a become desired temperatures, and it is maintained until the temperature is stabilized (temperature stabilizing process).

In the temperature raising process and the temperature stabilizing process, H atoms terminated by the wafer cleaning process are detached from the surface of the wafer, and oxygen atoms exist in the process chamber 24 because the temperature of impurities or moisture remaining on the inner wall of the reaction tube is raised. The oxygen atoms bond with the Ge atoms of the wafer surface instead of the detached hydrogen atoms and thus a Ge oxide film GeOₓ is formed.

Next, when the temperature of the inside of the process chamber 24 is stabilized, an etching gas is supplied by the second gas supply system 32 and etching of the wafer a is performed as preprocessing to remove the oxide film or impurities formed on the wafer surface. Thereafter, selective epitaxial growth processing is performed on the wafer a. First, in response to a command from the control device 60, the rotation mechanism 38 is driven to rotate the boat 16 at a predetermined rotation speed. Then, in response to a command from the control device 60, the first MFCs 53a, 53b, and 53c are controlled, the first valves 63a, 63b, and 63c are opened, a raw material gas (Si-containing gas) is supplied from the first gas supply ports 40a, 40b, and 40c through the first gas supply nozzles 42a, 42b and 42c to the process chamber 24, and a Si film is deposited for a predetermined time on the surface of the wafer a at which the SiGe film or the Ge film is exposed and the surface of the wafer a that is covered with an insulating film (raw material gas supply process). While the raw material gas is supplied to the process chamber 24, the fifth MFC 57 and the fifth valve 67 are controlled in response to a command from the control device 60, the purge gas is supplied to the second gas supply nozzles 44a, 44b, and 44c, and the entry of the raw material gas into the second gas supply pipe is suppressed. Also, in the deposition process, since the inner walls of the first gas supply nozzles 42a, 42b, and 42c and the inner wall of the reaction tube 26 are also exposed to the raw material gas like the wafer a, a Si film is deposited thereon.

Next, in response to a command from the control device 60, the first MFCs 53a, 53b, and 53c and the first valves 63a, 63b, and 63c are controlled to stop the supply of the raw material gas into the process chamber 24. Also, the fourth MFC 56 and the fourth valve 66 are controlled to supply the purge gas from the first gas supply ports 40a, 40b, and 40c through the first gas supply nozzles 42a, 42b, and 42c. In this case, the purge gas is also supplied from the second gas supply ports 43a, 43b, and 43c, and the raw material gas (Si containing gas) remaining in the process chamber 24 is removed (first purge process).

Next, in response to a command from the control device 60, the fifth MFC 57 and the fifth valve 67 are controlled to stop the supply of the purge gas to the second gas supply nozzles 44a, 44b, and 44c. Thereafter, the third MFCs 55a, 55b, and 55c and the third valves 65a, 65b, and 65c are controlled to supply the etching gas from the second gas supply ports 43a, 43b, and 43c through the second gas supply nozzles 44a, 44b, and 44c to the process chamber 24. Thus, the Si film formed on the surface of the insulating film is removed (etching process). While the etching gas is supplied to the process chamber 24, the fourth MFC 56 and the fourth valve 66 are controlled in response to a command from the control device 60, the purge gas is supplied to the first gas supply nozzles 42a, 42b, and 42c, and the entry of the etching gas into the first gas supply nozzle is suppressed. Also, in the portion exposed to the etching gas, such as the inner wall of the reaction tube 26, the Si film formed in the film deposition process is also etched simultaneously. On the other hand, since the etching gas does not enter the first gas supply pipe, the Si film deposited on the first gas supply pipe is not etched.

Next, in response to a command from the control device 60, the third MFCs 55a, 55b, and 55c and the third valves 65a, 65b, and 65c are controlled to stop the supply of the etching gas into the process chamber 24. Also, the fifth MFC 57 and the fifth valve 67 are controlled to supply the purge gas from the second gas supply ports 43a, 43b, and 43c through the second gas supply nozzles 44a, 44b, and 44c. In this case, the purge gas is also supplied from the first gas supply ports 40a, 40b, and 40c, and the etching gas (halogen-containing gas) remaining in the process chamber 24 is removed (second purge process).

The above raw material gas supply (film deposition) process, the first purge process, the etching process, and the second purge process are repeated in turn to selectively grow a Si film of a predetermined thickness only on the surface of the wafer a at which the SiGe film or the Ge film is exposed (film deposition process). Thereafter, an inert gas (for example, nitrogen (N₂) gas) is supplied to the inside of the process chamber 24, the atmosphere of the inside of the process chamber 24 is replaced with the inert gas (N₂ purge process), the pressure of the inside of the process chamber 24 is returned to the atmospheric pressure (atmospheric pressure process), an elevating motor (not illustrated) is driven to carry out the boat 16 holding the processed wafer a from the inside of the process chamber 24, and then the furnace port portion is closed by the furnace port gate valve 29 (boat unload process). Thereafter, the processed wafer a is cooled in a standby chamber (not illustrated) (wafer cooling process). The wafer a cooled to a predetermined temperature is received in the wafer cassette 12 by using the transfer mechanism 14 (wafer carrying process), and processing of the wafer a is ended.

A detailed example of the cap layer forming process will be described below with reference to the detailed example described in the above channel portion forming process. The planarized/shaped wafer is carried to the cleaning apparatus, the wafer is cleaned by the cleaning apparatus, for example, at 1% DHF for 60 seconds to remove impurities or a natural oxide film formed on the surface of the wafer, and it is terminated by hydrogen atoms.

The cleaned wafer is loaded into the process chamber 24 mounted on the boat 16 by an in-plant carrying apparatus (not illustrated). Thereafter, the inside of the process chamber 24 is decompressed by the vacuum pump 59, and then the temperature of the atmosphere inside the process chamber 24 is raised to about 400° C. by the heater 22. In this case, terminated hydrogen atoms are detached from the surface of the wafer, and oxygen atoms exist in the process chamber 24 because the temperature of impurities or moisture remaining on the inner wall of the reaction tube 26 is raised. The oxygen atoms bond with the Ge atoms of the wafer surface instead of the detached hydrogen atoms and thus a Ge oxide film GeOₓ is formed.

When the temperature of the inside of the process chamber 24 is raised to about 400° C. by the temperature raising process, a Cl₂ gas is supplied to the inside of the process chamber 24 as pre-cleaning, and the surface of a SiGe film with a thickness of 350 nm deposited as the channel portion is etched by about 50 Å.

After one or both of the Ge oxide film and impurities on the wafer surface are removed by pre-cleaning, the temperature of the inside of the process chamber 24 is raised to about 520° C. as a film deposition process, and a process of sequentially supplying a SiH₄ gas as a raw material gas, a Cl₂ gas as an etching gas, and an H₂ gas as a purge gas is repeated in turn, so that such as a Si film is epitaxially grown to a thickness of about 50 nm to be formed as the cap layer.

When the desired film is formed as the cap layer in the channel portion, the inside of the process chamber 24 is purged by an N₂ gas and the boat 16 is unloaded.

When the SiGe film or the Ge film provided in the channel portion has a higher etching rate than the Si film and it is pre-cleaned at a process temperature equal to the process temperature for formation of the Si film as the cap layer, it is difficult to control the etching rate of the SiGe film or the Ge film. Therefore, the process temperature for pre-cleaning needs to be lower than the film deposition temperature of the cap layer, and the process temperature for pre-cleaning in the present embodiment may be preferably in a temperature range of 400° C. to 500° C.

Also, as for the type of the gas used as the raw material gas for Si film deposition, the Si-containing gas may be a Si atom-containing gas such as SiH₄, Si₂H₆, SiH₂Cl₂, SiHCl₃, or SiCl₄. Also, the etching gas is not limited to the Cl-containing gas such as a hydrogen chloride (HCl) gas or a chlorine (Cl₂) gas, but may be a halogen-containing gas such as a fluorine (F₂) gas, a hydrogen fluoride (HF) gas, or a chlorine trifluoride (ClF₃) gas.

(Analysis of Epitaxial Interface)

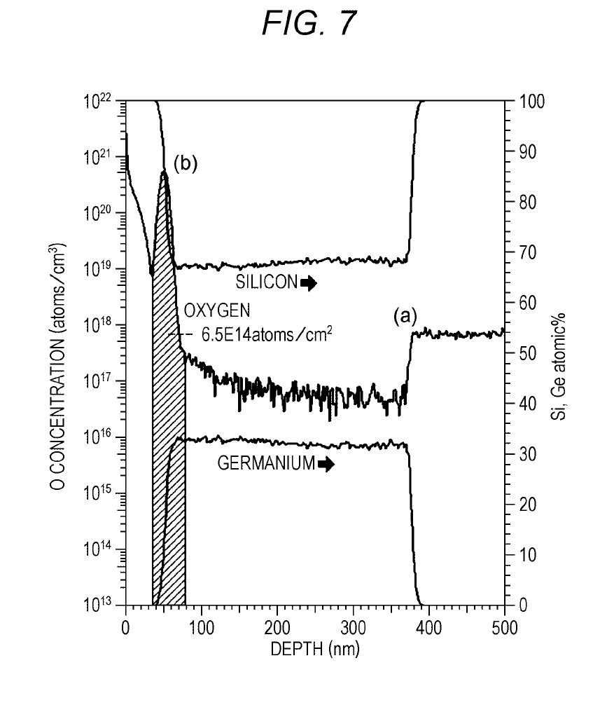

FIG. 7 illustrates the results of measurement of an impurity concentration of the epitaxial interface by a secondary ionization mass spectrometer (SIMS) with respect to the wafer after the above channel portion forming process, the planarization/shaping process of the substrate surface, and the cap layer forming process. The horizontal axis represents a depth from the surface, the left vertical axis represents a concentration of oxygen atoms in the film, and the right vertical axis represents a ratio between Si atoms and Ge atoms. A depth margin (a depth of about 360 nm to 400 nm) denoted by (a) of FIG. 7 represents the interface where the SiGe film is epitaxially grown on the Si substrate in the channel portion forming process, a right deep range of 400 nm represents the Si substrate, and the left side represents a concentration profile of oxygen atoms in the SiGe film. As illustrated in (a) of FIG. 7, it may be determined that an oxygen concentration peak is not observed in the SiGe/Si substrate interface and a good epitaxial interface may be obtained.

On the other hand, a depth margin (a depth of about 40 nm to 80 nm) denoted by (b) of FIG. 7 represents the interface where the Si film is epitaxially grown in the cap layer forming process, and an oxygen concentration peak of about 1E21 atoms/cm³ is observed in the Si/SiGe interface. When an oxygen dose amount (integrated value: an oblique line range of FIG. 7) in the film is calculated from the SIMS profile, it may be determined that oxygen atoms are contained at a concentration of 6.5E14 atoms/cm² and the optimal epitaxial interface may not be obtained.

Although 50 Å etching is performed in the channel portion forming process and the cap layer forming process like the pre-cleaning, oxygen is not removed from the Si/SiGe interface. The reason for this is that, since the bond energy of Si—O is about 403.7 kJ/mol and the bond energy of Ge—O is relatively low as about 356.9 kJ/mol, Ge atoms are easily oxidized and a Ge oxide film is formed because oxygen atoms etched by Cl₂ again bond with Ge atoms of the SiGe surface before they are purged by the purge gas.

### Second Embodiment

Next, a second embodiment will be described.

In the first embodiment described above, in order to remove the natural oxide film formed on the SiGe film or the Ge film as the channel portion, pre-cleaning is performed by using a halogen-containing gas as the etching gas, and then the Si film as the cap layer is epitaxially grown by the Si-containing gas. However, in the present embodiment, it is different from the first embodiment that the Si-containing gas is supplied before the supply of the etching gas as the pre-cleaning of the SiGe or Ge film surface, and Ge atoms existing on the SiGe film surface or the Ge film surface and Si atoms caused by the Si-containing gas are bonded together, so that the SiGe film surface or the Ge film surface is terminated by Si atoms.

A detailed example will be described below. Also, since the channel portion forming process and the substrate surface planarization/shaping process in the present embodiment are the same as those in the first embodiment, redundant descriptions thereof will be omitted.

(Formation of Cap Layer)

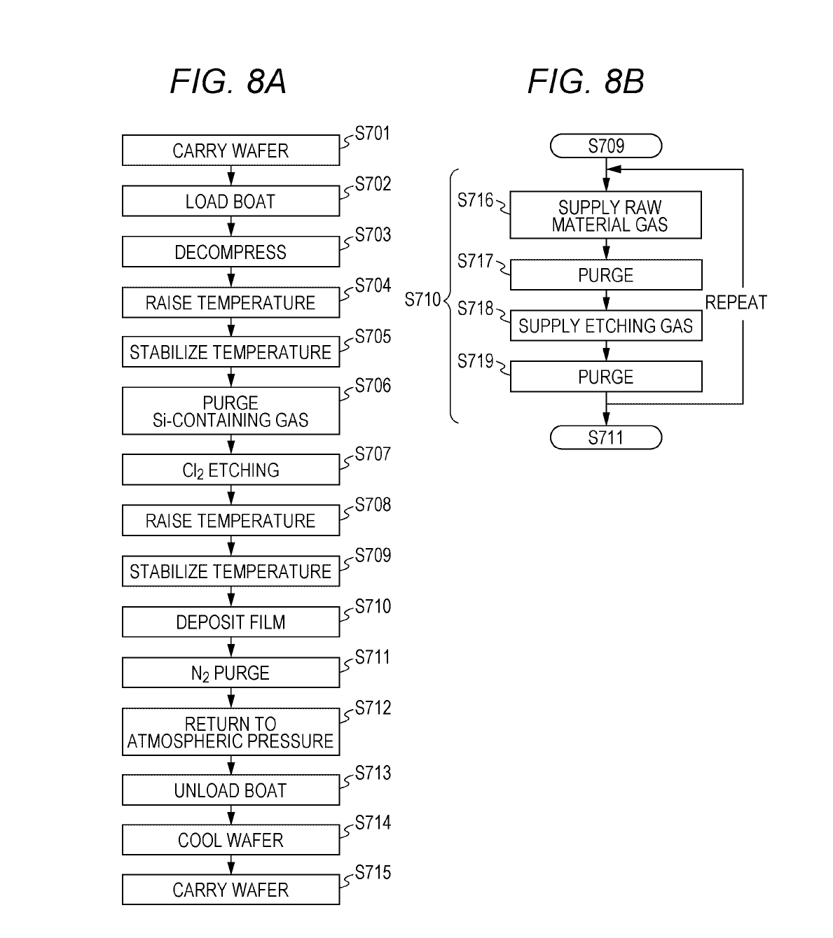

FIGS. 8A and 8B are diagrams illustrating a cap layer forming process flow according to the present embodiment.

Like in the first embodiment, the wafer a received in the wafer cassette 12 is transferred to the boat 16 as a substrate holding unit by using the transfer mechanism 14 (S701). Also, the wafer a has a surface at which a SiGe film or a Ge film is exposed and a surface that is covered with an insulating film (SiN or SiO₂). Next, the boat 16 holding the unprocessed wafer a is inserted into the process chamber 24 by moving the furnace port gate valve 29, opening a furnace port portion, and driving an elevating motor (not illustrated) (S702). Next, in response to a command from the control device 60, an exhaust valve 62 is opened to exhaust the atmosphere of the inside of the process chamber 24 and decompress the inside of the process chamber 24 (S703). Then, by controlling the heater 22 by the control device 60, the temperature of the process chamber 24 is raised (S704) such that the temperature of the inside of the process chamber 24 and the temperature of the wafer a become desired temperatures, and it is maintained until the temperature is stabilized (S705).

Herein, since the temperature of the process chamber 24 is raised (S704), H atoms are detached from Ge atoms on the SiGe film or the Ge film that are the surfaces of the wafer a, and Ge atoms are exposed on the SiGe film or the Ge film. This will be described later.

When the inside of the process chamber 24 is stabilized at a predetermined temperature for pre-cleaning, the valves 63a, 63b, and 63c are opened to supply a SiH₄ gas as a Si-containing gas from the gas supply nozzles 42a, 42b, and 42c, and Ge atoms exposed on the SiGe film or the Ge film and Si atoms or the exposed Ge atoms and SiHₓ molecules resulting from the detachment of H atoms from the SiH₄ gas are bonded together (S706).

After the SiH₄ gas as the Si-containing gas is supplied for a predetermined time or at a predetermined flow rate, a Cl₂ gas as the etching gas is supplied, and either one or both of a Ge—SiHₓ bond and a Ge—Si bond formed on at least the SiGe film or the Ge film is etched and removed (S707).

The pre-cleaning before the deposition of the cap layer is performed in at least one cycle of S706 and S707 described above.

After the pre-cleaning, the heater 22 is again controlled to raise the temperature of the inside of the process chamber 24 to a temperature for deposition of the cap layer (S708), and when the temperature of the inside of the process chamber 24 is stabilized at a desired temperature (S709), a film deposition process of forming the cap layer on the SiGe film or the Ge film is performed (S710).

First, in response to a command from the control device 60, the rotation mechanism 38 is driven to rotate the boat 16 at a predetermined rotation speed. Then, in response to a command from the control device 60, the first MFCs 53a, 53b, and 53c are controlled, the first valves 63a, 63b, and 63c are opened, a raw material gas (Si-containing gas) is supplied from the first gas supply ports 40a, 40b, and 40c through the first gas supply nozzles 42a, 42b and 42c to the process chamber 24, and a Si film is deposited for a predetermined time on the SiGe film or the Ge film of the wafer a (raw material gas supply process). While the raw material gas is supplied to the process chamber 24, the fifth MFC 57 and the fifth valve 67 are controlled in response to a command from the control device 60, the purge gas is supplied to the second gas supply nozzles 44a, 44b, and 44c, and the entry of the raw material gas into the second gas supply pipe is suppressed. Also, in the deposition process, since the inner walls of the first gas supply nozzles 42a, 42b, and 42c and the inner wall of the reaction tube 26 are also exposed to the raw material gas like the wafer a, a Si film is deposited thereon.

Next, in response to a command from the control device 60, the first MFCs 53a, 53b, and 53c and the first valves 63a, 63b, and 63c are controlled to stop the supply of the raw material gas into the process chamber 24. Also, the fourth MFC 56 and the fourth valve 66 are controlled to supply the purge gas from the first gas supply ports 40a, 40b, and 40c through the first gas supply nozzles 42a, 42b, and 42c. In this case, the purge gas is also supplied from the second gas supply ports 43a, 43b, and 43c, and the raw material gas (Si containing gas) remaining in the process chamber 24 is removed (first purge process).

Next, in response to a command from the control device 60, the fifth MFC 57 and the fifth valve 67 are controlled to stop the supply of the purge gas to the second gas supply nozzles 44a, 44b, and 44c. Thereafter, the third MFCs 55a, 55b, and 55c and the third valves 65a, 65b, and 65c are controlled to supply the etching gas from the second gas supply ports 43a, 43b, and 43c through the second gas supply nozzles 44a, 44b, and 44c to the process chamber 24. Thus, the Si film formed on the surface of the insulating film is removed (etching process). While the etching gas is supplied to the process chamber 24, the fourth MFC 56 and the fourth valve 66 are controlled in response to a command from the control device 60, the purge gas is supplied to the first gas supply nozzles 42a, 42b, and 42c, and the entry of the etching gas into the first gas supply nozzle is suppressed. Also, in the portion exposed to the etching gas, such as the inner wall of the reaction tube 26, the Si film formed in the film deposition process is also etched simultaneously. On the other hand, since the etching gas does not enter the first gas supply pipe, the Si film deposited on the first gas supply pipe is not etched.

Next, in response to a command from the control device 60, the third MFCs 55a, 55b, and 55c and the third valves 65a, 65b, and 65c are controlled to stop the supply of the etching gas into the process chamber 24. Also, the fifth MFC 57 and the fifth valve 67 are controlled to supply the purge gas from the second gas supply ports 43a, 43b, and 43c through the second gas supply nozzles 44a, 44b, and 44c. In this case, the purge gas is also supplied from the first gas supply ports 40a, 40b, and 40c, and the etching gas (halogen-containing gas) remaining in the process chamber 24 is removed (second purge process).

The above raw material gas supply (film deposition) process, the first purge process, the etching process, and the second purge process are repeated in turn to selectively grow a Si film of a predetermined thickness only on the SiGe film or the Ge film of the wafer a (film deposition process). Thereafter, an inert gas (for example, nitrogen (N₂) gas) is supplied to the inside of the process chamber 24, the atmosphere of the inside of the process chamber 24 is replaced with the inert gas (N₂ purge process), the pressure of the inside of the process chamber 24 is returned to the atmospheric pressure (atmospheric pressure process), an elevating motor (not illustrated) is driven to carry out the boat 16 holding the processed wafer a from the inside of the process chamber 24, and then the furnace port portion is closed by the furnace port gate valve 29 (boat unload process). Thereafter, the processed wafer a is cooled in a standby chamber (not illustrated) (wafer cooling process). The wafer a cooled to a predetermined temperature is received in the wafer cassette 12 by using the transfer mechanism 14 (wafer carrying process), and processing of the wafer a is ended.

A detailed example of the cap layer forming process according to the present embodiment will be described below with reference to the detailed example of the above channel portion forming process and the planarization/shaping process described in the first embodiment.

After the formation of the channel portion, the planarized/shaped wafer is carried to the cleaning apparatus, the wafer is cleaned by the cleaning apparatus, for example, at 1% DHF for 60 seconds to remove impurities or a natural oxide film formed on the surface of the wafer, and it is terminated by hydrogen atoms.

The cleaned wafer is loaded into the process chamber 24 mounted on the boat 16 by an in-plant carrying apparatus (not illustrated). Thereafter, the inside of the process chamber 24 is decompressed by the vacuum pump 59, and then the temperature of the atmosphere inside the process chamber 24 is raised to about 400° C. by the heater 22. In this case, terminated H atoms are detached from the surface of the wafer, and oxygen atoms exist in the process chamber 24 because the temperature of impurities or moisture remaining on the inner wall of the reaction tube 26 is raised. The oxygen atoms bond with the Ge atoms of the wafer surface instead of the detached hydrogen atoms and thus a Ge oxide film GeOₓ is formed.

When the temperature of the inside of the process chamber 24 is raised to about 400° C., a SiH₄ gas is supplied to the inside of the process chamber 24 as pre-cleaning, and Ge atoms of the SiGe film or the Ge film and Si atoms are bonded together, so that it is terminated by Si or SiHₓ. The SiH₄ gas not bonding with the Ge atoms is exhausted by the gas exhaust pipe 28 as a gas exhaust system. By this exhaustion, the oxygen atoms existing in the process chamber 24 are also exhausted from the inside of the process chamber 24.

Thereafter, the surface of the SiGe film or the Ge film of a thickness of 350 nm terminated by Si or SiHₓ is etched by about 50 Å.

After the impurities on the wafer surface are removed by pre-cleaning, the temperature of the inside of the process chamber 24 is raised to about 520° C. as a film deposition process, and a process of sequentially supplying a SiH₄ gas as a raw material gas, a Cl₂ gas as an etching gas, and an H₂ gas as a purge gas is repeated in turn, so that a Si film is epitaxially grown to a thickness of about 50 nm to be formed as the cap layer.

When the desired film is formed in the channel portion, the inside of the process chamber 24 is purged by an N₂ gas and the boat 16 is unloaded.

In the present embodiment, when SiH₄ purge is performed at a high temperature of 500° C. or more, since the Si film is grown and the oxygen atoms are get trapped before the removal of the oxygen atoms of the substrate surface, the temperature of the inside of the process chamber 24 for the supply of the SiH₄ gas as the Si-containing gas in the pre-cleaning needs to be lower than a Si film deposition temperature and may be preferably in a temperature range of 450° C. or less.

Also, as in the first embodiment, as for the type of the gas used as the raw material gas for Si film deposition, the Si-containing gas may be a Si atom-containing gas such as SiH₄, Si₂H₆, SiH₂Cl₂, SiHCl₃, or SiCl₄. Also, the etching gas is not limited to the Cl-containing gas such as a hydrogen chloride (HCl) gas or a chlorine (Cl₂) gas, but may be a halogen-containing gas such as a fluorine (F₂) gas, a hydrogen fluoride (HF) gas, or a chlorine trifluoride (ClF₃) gas.

(Analysis of Epitaxial Interface)

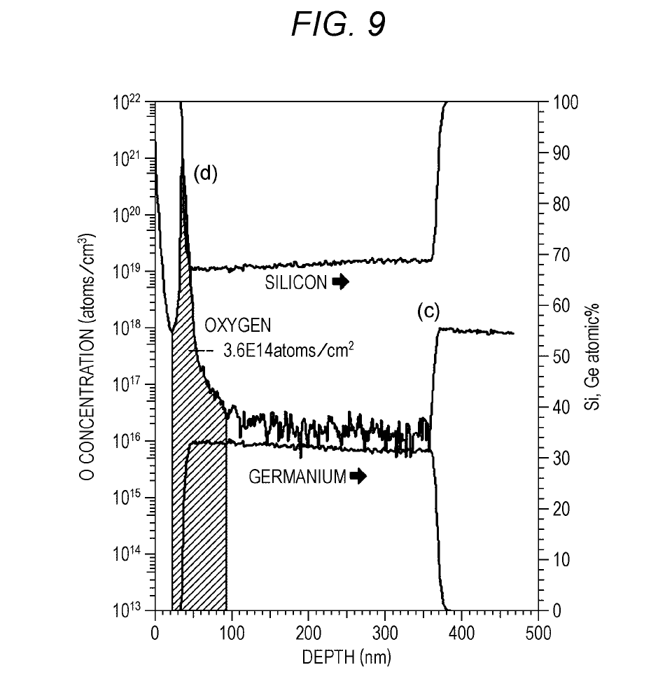

FIG. 9 illustrates the results of a SIMS analysis of the wafer on which the cap layer is formed according to the present embodiment.

The horizontal axis represents a depth from the surface, the left vertical axis represents a concentration of oxygen atoms in the film, and the right vertical axis represents a ratio between Si atoms and Ge atoms. A depth margin (a depth of about 350 nm to 400 nm) denoted by (c) of FIG. 9 represents the interface where the SiGe film is epitaxially grown on the Si substrate in the channel portion forming process, a right deep range of 400 nm represents the wafer, and the left side represents a concentration profile of oxygen atoms in the SiGe film. As illustrated in (c) of FIG. 9, it may be determined that an oxygen concentration peak is not observed in the SiGe/Si substrate interface and a good epitaxial interface may be obtained.

On the other hand, a depth margin (a depth of about 20 nm to 50 nm) denoted by (d) of FIG. 9 represents the interface where the Si film is epitaxially grown in the substrate surface planarization/shaping process. Although a peak value of about 1E21 atoms/cm³ is observed as in the related art, an oxygen dose amount (integrated value: an oblique line range of FIG. 9) in the film is calculated as about 3.6E14 atoms/cm². In comparison with the related art, it may be seen that the oxygen dose amount is halved and the epitaxial quality is improved, although a perfect epitaxial interface is not obtained.

The reason for this is that, although a dangling bond of the Si atom and the Ge atom of the wafer surface is terminated by hydrogen (H) atoms by the DHF cleaning performed by the cleaning apparatus after the substrate surface planarization/shaping process, the bond energy of Si atoms and H atoms (Si—H bond) is about 318 kJ/mol, the bond energy of Ge atoms and H atoms (Ge—H bond) is about 285 kJ/mol, the hydrogen termination is detached from about 500° C. when bonded to the Si atoms, and the hydrogen termination is detached from about 280° C. when bonded to the Ge atoms.

Thus, the temperature of the inside of the process chamber 24 is maintained at a temperature of 400° C. at which the Si—H bond is not cut off and the Ge—H bond is cut off, the dangling bond of the Ge atoms of the SiGe surface from which hydrogen atoms are detached by SiH₄ purging reacts with SiH₄ and is terminated by Si (a Ge—Si bond is formed), and the readhesion of oxygen atoms etched by Cl₂ to the Ge atoms of the SiGe film surface is suppressed.

Therefore, when a SiH₄ gas is supplied as a pre-cleaning gas, the temperature of the inside of the process chamber 24 needs to be set in a temperature range of 150° C. to 500° C. at which the Si—H bond is not cut off and the Ge—H bond is cut off, may be preferably set in a temperature range of 200° C. to 450° C., and may be more preferably set in a temperature range of 280° C. to 400° C.

According to the present embodiment, since SiH₄ purging is performed on the SiGe or Ge surface deposited on the wafer before Cl₂ etching, the readhesion of oxygen atoms to the SiGe or Ge surface may be prevented and a clean epitaxial film interface may be obtained. Accordingly, a Si epitaxial film that may be used with high crystallinity in the channel may be grown also on the SiGe or Ge surface.

### Third Embodiment

Next, a third embodiment will be described.

In the second embodiment described above, the Si-containing gas is supplied before the supply of the etching gas as the pre-cleaning of the SiGe or Ge film surface, the Ge atoms existing on the SiGe or Ge film surface and the Si atoms based on the Si-containing gas are bonded to form a Ge—Si bond, the etching gas is supplied to remove the Ge—Si bond, and substrate processing based on the Si-containing gas is performed after the temperature raising (S704) and the temperature stabilization (S705) are performed before pre-cleaning.

However, in the present embodiment, the Si-containing gas is supplied into the process chamber simultaneously with the start of temperature raising, it is bonded to the Ge atom existing on the SiGe film surface or the Ge film surface to form a Ge—Si bond, and an etching gas for removing the Ge—Si bond is supplied after the temperature of the inside of the process chamber is raised to the film deposition temperature.

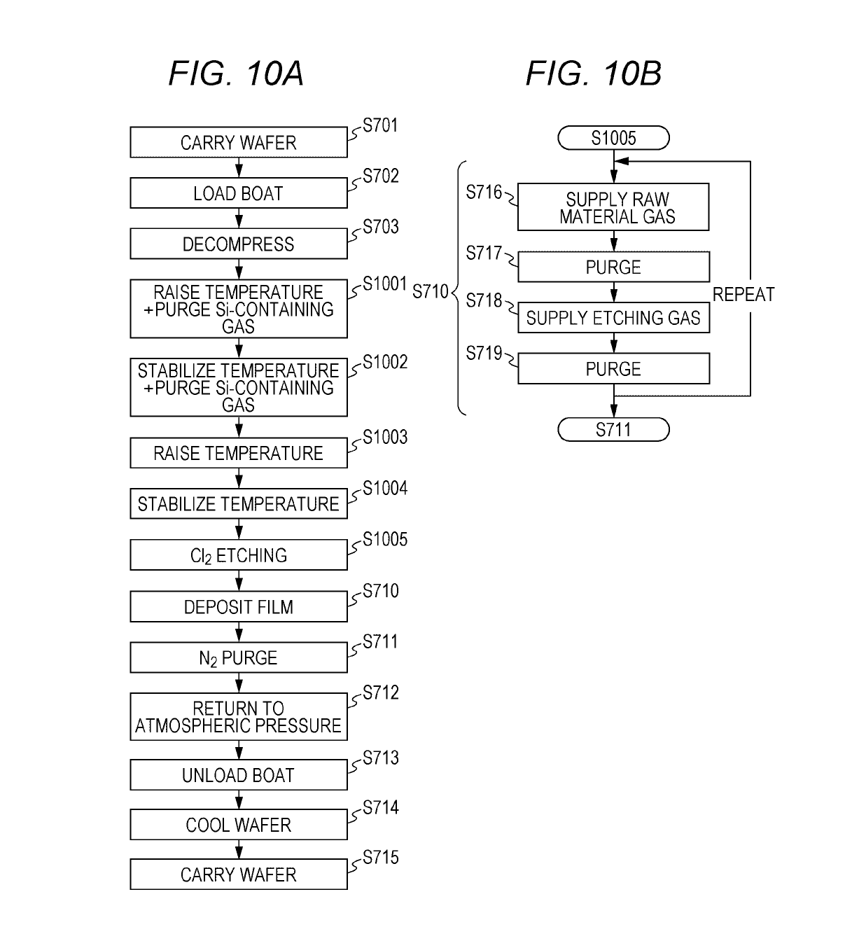

FIGS. 10A and 10B are diagrams illustrating a cap layer forming process flow according to the present embodiment.

The differences of the present embodiment from the second embodiment are the timing of supplying the Si-containing gas of pre-cleaning and the timing of supplying the etching gas. The same processes as in the second embodiment will be denoted by the same reference numerals as in the second embodiment, and redundant descriptions thereof will be omitted.

In detail, when the boat 16 as a substrate holding unit holding the wafer a is loaded into the process chamber 24 and the inside of the process chamber 24 is decompressed, the control device 60 controls the heater 22 such that the temperature of the inside of the process chamber 24 is raised to, for example, about 400° C. that is a predetermined pre-cleaning temperature.

At this time, the Si-containing gas, for example, a SiH₄ gas is supplied simultaneously (S1001), and the SiH₄ gas is also supplied while the temperature of the inside of the process chamber 24 is stabilized (S1002). After the SiH₄ gas is supplied at a predetermined flow rate or for a predetermined time, the temperature of the inside of the process chamber 24 is raised, for example, to 520° C. that is the film deposition temperature (S1003). When the temperature of the inside of the process chamber 24 is stabilized at 520° C. (S1004), an etching gas Cl₂ is supplied to remove the Ge—Si bond formed by supplying the SiH₄ gas (S1005). Thereafter, as in the second embodiment, film deposition processing is performed to perform substrate processing.

Due to this processing process, the time taken to complete the formation of the Ge—Si bond may be reduced, and the total processing time may be reduced.

(Analysis of Epitaxial Interface)

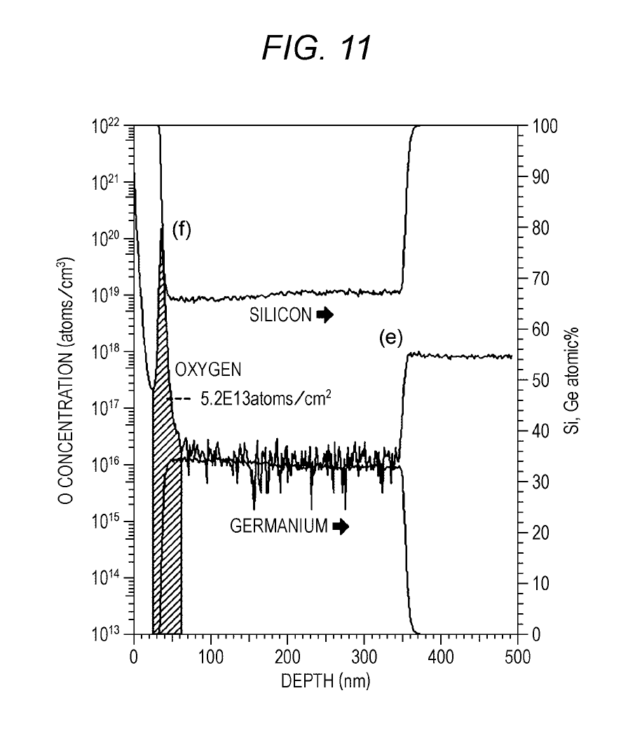

FIG. 11 illustrates the results of a SIMS analysis of the wafer on which the cap layer is formed according to the present embodiment.

The horizontal axis represents a depth from the surface, the left vertical axis represents a concentration of oxygen atoms in the film, and the right vertical axis represents a ratio between Si atoms and Ge atoms. A depth margin (a depth of about 340 nm to 400 nm) denoted by (e) of FIG. 11 represents the interface where the SiGe film is epitaxially grown on the Si substrate in the channel portion forming process, a right deep range of 400 nm represents the wafer, and the left side represents a concentration profile of oxygen atoms in the SiGe film. As illustrated in (e) of FIG. 11, it may be seen that an oxygen concentration peak is not observed in the SiGe/Si substrate interface and a good epitaxial interface may be obtained.

On the other hand, a depth margin (a depth of about 20 nm to 50 nm) denoted by (f) of FIG. 11 represents the interface where the Si film is epitaxially grown in the substrate surface planarization/shaping process. An oxygen (O) peak value of about 10E20 atoms/cm is observed, and an oxygen dose amount (integrated value: an oblique line range of FIG. 11) in the film is calculated as about 5.2E13 atoms/cm². In comparison with the related art, it may be seen that the oxygen dose amount is considerably reduced and the epitaxial quality is improved, although a perfect epitaxial interface is not obtained.

The reason for this is that, although a dangling bond of the Si atom and the Ge atom of the wafer surface is terminated by hydrogen (H) atoms by the DHF cleaning performed by the cleaning apparatus after the substrate surface planarization/shaping process, the bond energy of Si atoms and H atoms (Si—H bond) is about 318 kJ/mol, the bond energy of Ge atoms and H atoms (Ge—H bond) is about 285 kJ/mol, the hydrogen termination is deviated from about 500° C. when bonded to the Si atoms, and the hydrogen termination is deviated from about 280° C. when bonded to the Ge atoms.

Thus, by flowing SiH₄ in the process of raising the temperature (generally, about 200° C.) of the inside of the process chamber 24 at the boat loading to the film deposition temperature, the atmosphere inside the process chamber 24 is filled with SiH₄ at a temperature that is lower than 280° C. at which the Ge—H bond on the SiGe film or the Ge film is cut off. When the temperature reaches a temperature of about 280° C. at which the Ge—H bond is cut off and hydrogen atoms are detached from the hydrogen termination, the atmosphere inside the process chamber 24 is replaced with the SiH₄ gas, the dangling bond of the Ge atoms after the detachment of the hydrogen atoms is easily terminated by Si or SiHₓ. Due to this reaction, the adhesion of the oxygen atoms to the dangling bond of the Ge atoms is suppressed.

Therefore, when the SiH₄ gas is supplied as a pre-cleaning gas, the temperature of the inside of the process chamber 24 needs to be set in a temperature range of 100° C. or more that is lower than a temperature range in which the Si—H bond is not cut off and the Ge—H bond is cut off, may be preferably set in a temperature range of 100° C. to 500° C., and may be more preferably set in a temperature range of 200° C. to 400° C.

According to the present embodiment, since SiH₄ is supplied during temperature raising and oxygen purging is performed on the SiGe film or Ge film surface deposited on the wafer, the readhesion of oxygen atoms to the SiGe or Ge surface may be prevented and a clean epitaxial film interface may be obtained. Accordingly, a Si epitaxial film that may be used with high crystallinity in the channel may be grown also on the SiGe or Ge surface.

Although the embodiments of the present invention have been described, the above embodiments, the respective modifications, and the applications thereof may be used in combination and the same effect may be obtained.

For example, in each of the above embodiments, the SiGe film or the Ge film is formed as the channel portion, and the epitaxial Si film formed on the SiGe film or the Ge film is formed as the cap layer. However, the present invention is not limited thereto, and the SiGe film or the Ge film may be formed as an underlayer film of the channel portion and the epitaxial Si film may be formed as the channel portion. And more specifically, if it is a case where an epitaxial silicon film is formed on a SiGe film or Ge film, it is possible to apply the present invention.

Also, each of the above embodiment, the generation of an oxide film in the SiGe film or the Ge film is suppressed by supplying the Si-containing gas as preprocessing. However, the present invention is not limited thereto, and the carrier gas such as the hydrogen gas (H₂ gas) may be supplied simultaneously with the Si-containing gas.

Also, the processing process used for substrate processing in each embodiment may be stored as a program on a recording device (or recording medium) such as flash memory or a hard disk drive (HDD) that is not provided for the control system 23 (or the control device 60). In order to obtain a predetermined result by executing the respective procedures of the substrate processing process in the control system 23 of the control device 60, a combined program may be described as a program recipe.

In each of the above embodiments, the program recipe and a control program controlling the respective apparatuses may be collectively referred to as a program.

Also, in each of the above embodiments, the control system 23 and the control device 60 may include a special-purpose computer or a general-purpose computer. For example, in each of the above embodiments, the control system 23 and the control device 60 may be constructed by installing a program into a computer by using a memory device storing the above program.

Also, in each of the above embodiments, the substrate processing apparatus is illustrated as a hot wall type vertical decompression apparatus. However, the substrate processing apparatus may be a so-called cold wall type vertical decompression apparatus which is directly heating a processing object by a lamp heating apparatus and is not limited to vertical type apparatuses. The substrate processing apparatus may be a single wafer type substrate processing apparatus that mounts and processes a plurality of substrates on the same surface. Also, the substrate processing apparatus is not limited to decompression apparatuses and may be an apparatus that performs processing under an atmospheric pressure or a positive pressure.

As described above, the present invention may provide a semiconductor device manufacturing technology that makes it possible to increase a driving speed and reduce power consumption.

<Preferred Aspects of the Present Invention>

Hereinafter, preferred aspects of the present invention will be supplementarily noted.

(Supplementary Note 1)

According to an aspect of the present invention, a method of manufacturing a semiconductor device or a substrate processing method includes:

carrying a substrate, which has a Ge-containing film on at least a portion of a surface thereof, into a process chamber;

heating an inside of the process chamber, into which the substrate is carried, to a first process temperature; and

terminating a surface of the Ge-containing film, which is exposed at a portion of the surface of the substrate, by Si by supplying at least a Si-containing gas to the inside of the process chamber heated to the first process temperature.

(Supplementary Note 2)

According to another aspect of the present invention, a method of manufacturing a semiconductor device or a substrate processing method includes:

carrying a substrate, which has a Ge-containing film on at least a portion of a surface thereof, into a process chamber;

heating an inside of the process chamber, into which the substrate is carried, to a first process temperature; and

terminating a surface of the Ge-containing film, which is exposed at a portion of the surface of the substrate, by Si by supplying at least a Si-containing gas to the inside of the process chamber between a time when the substrate is carried into the process chamber and a time when the inside of the process chamber is stabilized at the first process temperature.

(Supplementary Note 3)

In the method of manufacturing a semiconductor device described in Supplementary Note 1 or 2, the first process temperature is lower than 500° C.

(Supplementary Note 4)

In the method of manufacturing a semiconductor device described in any one of Supplementary Notes 1 to 3, the first process temperature is higher than 100° C.

(Supplementary Note 5)

In the method of manufacturing a semiconductor device described in any one of Supplementary Notes 1 to 4, the first process temperature is set in a temperature range of 100° C. to 500° C.

(Supplementary Note 6)

In the method of manufacturing a semiconductor device described in any one of Supplementary Notes 1 to 5, the first process temperature is set in a temperature range of 200° C. to 400° C.

(Supplementary Note 7)

In the method of manufacturing a semiconductor device described in any one of Supplementary Notes 2 to 6, the supply of the Si-containing gas is started at a timing of starting to heat the inside of the process chamber to the first process temperature.

(Supplementary Note 8)

In the method of manufacturing a semiconductor device described in any one of Supplementary Notes 1 to 7, the Si-containing gas is a SiH₄ gas.

(Supplementary Note 9)

The method of manufacturing a semiconductor device described in any one of Supplementary Notes 1 to 8 includes:

heating the inside of the process chamber to a second process temperature after terminating the surface of the Ge-containing film by Si; and

forming a predetermined film on the surface of the substrate by supplying a raw material gas to the inside of the process chamber heated to the second process temperature.

(Supplementary Note 10)

According to another aspect of the present invention, a substrate processing apparatus includes:

a process chamber configured to process a substrate;

a heating device configured to heat an inside of the process chamber;

a raw material gas supply system configured to supply at least a Si-containing gas to the process chamber; and

a control unit configured to control the heating device to heat the inside of the process chamber to a first process temperature after carrying the substrate, which has a Ge-containing film on at least a portion of a surface thereof, into the process chamber, and to control the raw material gas supply system to terminate a surface of the Ge-containing film, which is exposed at a portion of the surface of the substrate, by Si by supplying at least the Si-containing gas into the process chamber at a time point when the inside of the process chamber is heated to the first process temperature.

(Supplementary Note 11)

According to another aspect of the present invention, a substrate processing apparatus includes:

a process chamber configured to process a substrate;

a heating device configured to heat an inside of the process chamber;

a raw material gas supply system configured to supply at least a Si-containing gas to the process chamber; and

a control unit configured to control the heating device to heat the inside of the process chamber to a first process temperature after carrying the substrate, which has a Ge-containing film on at least a portion of a surface thereof, into the process chamber, and to control the raw material gas supply system to terminate a surface of the Ge-containing film by Si by continuously supplying at least the Si-containing gas to the inside of the process chamber between a time when the substrate is carried into the process chamber and a time when the inside of the process chamber is stabilized at the first process temperature.

(Supplementary Note 12)

In the substrate processing apparatus described in Supplementary Note 10 or 11, the control unit is configured to control the heating device such that the first process temperature is lower than 500° C.

(Supplementary Note 13)

In the substrate processing apparatus described in any one of Supplementary Notes 10 to 12, the control unit is configured to control the heating device such that the first process temperature is higher than 100° C.

(Supplementary Note 14)

In the substrate processing apparatus described in any one of Supplementary Notes 10 to 13, the control unit is configured to control the heating device such that the first process temperature is in a temperature range of 100° C. to 500° C.

(Supplementary Note 15)

In the substrate processing apparatus described in any one of Supplementary Notes 10 to 14, the Si-containing gas is a SiH₄ gas.

(Supplementary Note 16)

According to another aspect of the present invention, there is provided a program or a non-transitory computer-readable recording medium storing the program, wherein the program causes a computer to perform:

a procedure of carrying a substrate, which has a Ge-containing film on at least a portion of a surface thereof, into a process chamber;

a procedure of heating an inside of the process chamber, into which the substrate is carried, to a first process temperature; and

a procedure of terminating a surface of the Ge-containing film, which is exposed at a portion of the surface of the substrate, by Si by supplying at least a Si-containing gas to the inside of the process chamber heated to the first process temperature.

(Supplementary Note 17)

According to another aspect of the present invention, there is provided a program or a non-transitory computer-readable recording medium storing the program, wherein the program causes a computer to perform:

a procedure of carrying a substrate, which has a Ge-containing film on at least a portion of a surface thereof, into a process chamber;

a procedure of heating an inside of the process chamber, into which the substrate is carried, to a first process temperature; and

a procedure of terminating a surface of the Ge-containing film, which is exposed at a portion of the surface of the substrate, by Si by supplying at least a Si-containing gas to the inside of the process chamber between a time when the substrate is carried into the process chamber and a time when the inside of the process chamber is stabilized at the first process temperature.

(Supplementary Note 18)

According to another aspect of the present invention, a method of manufacturing a semiconductor device includes: forming a Ge-containing film on at least a portion of a surface of a substrate; planarizing the surface of the substrate on which the Ge-containing film is formed; carrying a substrate holding the planarized substrate into a process chamber; raising the temperature of an inside of the process chamber to a first process temperature by a heating device; supplying an etching gas at the first process temperature; raising the temperature of the inside of the process chamber to a second process temperature, which is higher than the first process temperature, by the heating device after the supplying of the etching gas; and supplying a raw material gas at the second process temperature.

(Supplementary Note 19)

According to another aspect of the present invention, a substrate processing method includes: carrying a substrate, which has a Ge-containing film on at least a portion of a surface thereof, into a process chamber; raising the temperature of an inside of the process chamber to a first process temperature by a heating device; supplying an etching gas at the first process temperature; raising the temperature of the inside of the process chamber to a second process temperature, which is higher than the first process temperature, by the heating device after the supplying of the etching gas; and supplying a raw material gas at the second process temperature.

What is claimed is:

1. A method of manufacturing a semiconductor device, comprising:
carrying a substrate, which has a Ge-containing film on at least a portion of a surface thereof, into a process chamber;
heating an inside of the process chamber, into which the substrate is carried, to a first process temperature; and
terminating a surface of the Ge-containing film, which is exposed at a portion of the surface of the substrate, by Si by supplying at least a Si-containing gas to the inside of the process chamber heated to the first process temperature.

2. The method according to claim 1, wherein the first process temperature is lower than 500° C.

3. The method according to claim 1, wherein the first process temperature is higher than 100° C.

4. The method according to claim 1, wherein the first process temperature is set in a temperature range of 100° C. to 500° C.

5. The method according to claim 1, wherein the first process temperature is set in a temperature range of 200° C. to 400° C.

6. The method according to claim 1, wherein the Si-containing gas is a SiH₄ gas.

7. The method according to claim 1, comprising:
heating the inside of the process chamber to a second process temperature by a heating device after the terminating of the surface of the Ge-containing film by Si; and
forming a predetermined film on the surface of the substrate by supplying a raw material gas from a raw material gas supply system after the heating of the inside of the process chamber to the second process temperature.

8. A method of manufacturing a semiconductor device, comprising:
carrying a substrate, which has a Ge-containing film on at least a portion of a surface thereof, into a process chamber;
heating an inside of the process chamber, into which the substrate is carried, to a first process temperature; and
terminating a surface of the Ge-containing film, which is exposed at a portion of the surface of the substrate, by Si by supplying at least a Si-containing gas to the inside of the process chamber between a time when the substrate is carried into the process chamber and a time when the inside of the process chamber is stabilized at the first process temperature.

9. The method according to claim 8, wherein the first process temperature is lower than 500° C.

10. The method according to claim 8, wherein the first process temperature is higher than 100° C.

11. The method according to claim 8, wherein the first process temperature is set in a temperature range of 100° C. to 500° C.

12. The method according to claim 8, wherein the first process temperature is set in a temperature range of 200° C. to 400° C.

13. The method according to claim 8, wherein the supply of the Si-containing gas is started at a timing of starting to heat the inside of the process chamber to the first process temperature.

14. The method according to claim 8, wherein the Si-containing gas is a SiH₄ gas.

15. The method according to claim 8, comprising:
heating the inside of the process chamber to a second process temperature by a heating device after the terminating of the surface of the Ge-containing film by Si; and
forming a predetermined film on the surface of the substrate by supplying a raw material gas from a raw material gas supply system after the heating of the inside of the process chamber to the second process temperature.

16. A substrate processing apparatus comprising:
a process chamber configured to process a substrate;
a heating device configured to heat an inside of the process chamber;
a raw material gas supply system configured to supply at least a Si-containing gas to the process chamber; and
a control unit configured to control the heating device to heat the inside of the process chamber to a first process temperature after carrying the substrate, which has a Ge-containing film on at least a portion of a surface thereof, into the process chamber, and to control the raw material gas supply system to terminate a surface of the Ge-containing film, which is exposed at a portion of the surface of the substrate, by Si by supplying at least the Si-containing gas to the inside of the process chamber at a time point when the inside of the process chamber is heated to the first process temperature.

17. A non-transitory computer-readable storage medium storing a program comprising:
a procedure of carrying a substrate, which has a Ge-containing film on at least a portion of a surface thereof, into a process chamber;
a procedure of heating an inside of the process chamber, into which the substrate is carried, to a first process temperature; and
a procedure of terminating a surface of the Ge-containing film, which is exposed at a portion of the surface of the substrate, by Si by supplying at least a Si-containing gas to the inside of the process chamber heated to the first process temperature.
